(19) United States
(12) Patent Application Publication
(10) Pub. No.: US 2026/0223576 A1
(43) Pub. Date: Jul. 30, 2026

(54) LIGHT EMITTING DISPLAY DEVICE

(71) Applicant: LG Display Co., Ltd., Seoul (KR)

(72) Inventors: Hee Yeol KIM, Paju-si (KR); Hong Seok CHOI, Paju-si (KR)

(73) Assignee: LG Display Co., Ltd., Seoul (KR)

(21) Appl. No.: 19/453,746

(22) Filed: Jan. 20, 2026

(30) Foreign Application Priority Data
Jan. 24, 2025 (KR) 10-2025-0011987

(51) Int. Cl. H10K 59/80; H10K 59/35

(52) U.S. Cl. CPC H10K 59/876; H10K 59/35; H10K 59/80517; H10K 59/80518; H10K 59/80524

(57) ABSTRACT

A light emitting display device can include a substrate on which a red subpixel, a green subpixel, and a blue subpixel are disposed, and a first reflective electrode, a second reflective electrode, and a third reflective electrode respectively at the red subpixel, the green subpixel, and the blue subpixel. The light emitting display device can further include a first transparent anode, a second transparent anode, and a third transparent anode respectively on the first to third reflective electrodes, and a semi-transmissive cathode at each of the red, green and blue subpixels and opposite the first transparent anode, the second transparent anode, or the third transparent anode with an intermediate layer having the same vertical distance interposed therebetween.

### CROSS-REFERENCE TO RELATED APPLICATIONS

This application claims priority to Korean Patent Application No. 10-2025-0011987, filed in the Republic of Korea on Jan. 24, 2025, which is hereby incorporated by reference in its entirety as if fully set forth herein.

### BACKGROUND OF THE DISCLOSURE

### Field of the Disclosure

The present disclosure relates to a light emitting display device.

### Discussion of the Related Art

In recent years, a self-light emitting display device has been considered as a competitive application in order to achieve reduction in device size and vivid color display without necessity of a separate light source. Based on an internal light emitting material, the self-light emitting display device can be classified as an organic light emitting display device or an inorganic light emitting display device.

The self-light emitting display device includes a plurality of subpixels, wherein each subpixel is provided with a light emitting device without a separate light source in order to emit light outside.

In addition, with high resolution and high integration of the display device, a tandem structure comprising a plurality of common layers and a plurality of light emitting layers over a plurality of subpixels for light emitting has been considered. Thus, research for the tandem structure has been conducted.

### SUMMARY OF THE DISCLOSURE

Light emitting display devices are used for large-area displays, and there is a growing demand for the light emitting display devices to display images without any sense of disparity from various viewing angles.

Embodiments of the present disclosure provide a light emitting display device having high efficiency and high color reproduction in a large-area structure.

Embodiments of the present disclosure provide a light emitting display device configured such that the structure of a transparent anode provided between a reflective electrode and an intermediate layer is adjusted for each subpixel and a plurality of light emitting layers is vertically spaced apart from each other to realize a strong cavity structure.

Embodiments of the present disclosure provide a light emitting display device configured such that the vertical positions of a plurality of light emitting layers relative to a light emitting node are adjusted to reduce viewing angle sensitivity, thereby preventing or minimizing poor visual perception due to viewing angle changes.

Embodiments of the present disclosure provide a light emitting display device configured such that each subpixel overlaps a color filter to prevent or minimize external light reflection without a separate polarizer.

Embodiments of the present disclosure provide a light emitting display device configured such that subpixels commonly include an intermediate layer including a plurality of light emitting layers, whereby it is possible to achieve high yield and high luminance efficiency and to prevent or minimize a sense of disparity when the viewing angle changes.

A light emitting display device according to an embodiment of the present disclosure includes a substrate on which a red subpixel, a green subpixel, and a blue subpixel are disposed, a first reflective electrode, a second reflective electrode, and a third reflective electrode respectively at the red subpixel, the green subpixel, and the blue subpixel, a first transparent anode, a second transparent anode, and a third transparent anode respectively on the first reflective electrode, the second reflective electrode, and the third reflective electrode in contact therewith, a semi-transmissive cathode opposite the first transparent anode, the second transparent anode, and the third transparent anode with an intermediate layer having the same vertical distance interposed therebetween and a red filter on the semi-transmissive cathode of the red subpixel, a green filter on the semi-transmissive cathode of the green subpixel, and a blue filter on the semi-transmissive cathode of the blue subpixel.

The intermediate layer can comprise a red light emitting layer, a green light emitting layer, and a blue light emitting layer overlapping each other while being spaced apart from each other with a charge generation layer interposed therebetween.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a sectional view schematically showing a light emitting display device according to a first embodiment of the present disclosure;

FIG. 2 is a sectional view showing a light emitting display device according to an embodiment of the present disclosure;

FIG. 3 is a sectional view schematically showing a light emitting display device according to a second embodiment of the present disclosure;

FIG. 4 is a sectional view schematically showing a light emitting display device according to a third embodiment of the present disclosure;

FIG. 5 is an example of a contour map showing a blue light emitting layer corresponding to the light emitting display device according to the embodiment of FIG. 1;

FIG. 6 is an example of a contour map showing a green light emitting layer corresponding to the light emitting display device according to the embodiment of FIG. 1;

FIG. 7 is an example of a contour map showing a red light emitting layer corresponding to the light emitting display device according to the embodiment of FIG. 1;

FIG. 8 is a graph showing red efficiencies of first to fifth experimental examples according to the present disclosure;

FIG. 9 is a graph showing green efficiencies of the first to fifth experimental examples according to the present disclosure;

FIG. 10 is a graph showing blue efficiencies of the first to fifth experimental examples according to the present disclosure;

FIG. 11 is a graph showing the luminous efficacies of red, green, blue, and white and the color deviation characteristics according to the viewing angle variation when a light emitting layer is disposed at the maximum cavity position in a light emitting device according to the embodiment of FIG. 1;

FIG. 12 is a graph showing the color deviation characteristics of FIG. 11 for each viewing angle;

FIG. 13 is an example of a graph showing green intensity as a function of the distance from an upper surface of a transparent anode in the light emitting device according to the embodiment of FIG. 1;

FIG. 14 is an example of a graph showing red intensity as a function of the distance from the upper surface of the transparent anode in the light emitting device according to the embodiment of FIG. 1;

FIG. 15 is an example of a contour map of a blue subpixel at a viewing angle of 60° in the embodiment of FIG. 1;

FIG. 16 is an example of a contour map of a green subpixel at a viewing angle of 60° in the embodiment of FIG. 1; and

FIG. 17 is an example of a contour map of a blue subpixel at a viewing angle of 60° in the embodiment of FIG. 1.

### DETAILED DESCRIPTION OF THE DISCLOSURE

Reference will now be made in detail to various embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same can obscure the subject matter of the disclosure. In addition, the names of elements used in the following description are selected in consideration of clarity of description of the disclosure, and can differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items. Further, the terms “disclosure” and “present disclosure” are the same and interchangeably used.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “over”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first,” “second,” etc. can be used to describe a variety of components. These terms aim to distinguish the same or similar components from one another and do not limit the components. Accordingly, for example, throughout the specification, a “first” component can be the same as a “second” component within the technical concept of the present disclosure, unless specifically mentioned otherwise. Further, the term “can” fully encompasses all the meanings and coverages of the term “may” and vice versa.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, a hole transport layer and an electron transport layer.

Hereinafter, various embodiments of the present disclosure will be described with reference to the accompanying drawings. All the components of each display device/apparatus according to all embodiments of the present disclosure are operatively coupled and configured.

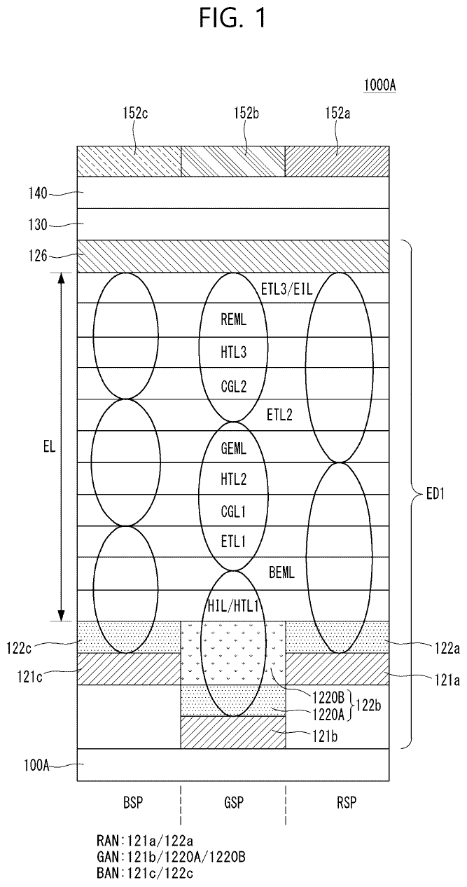

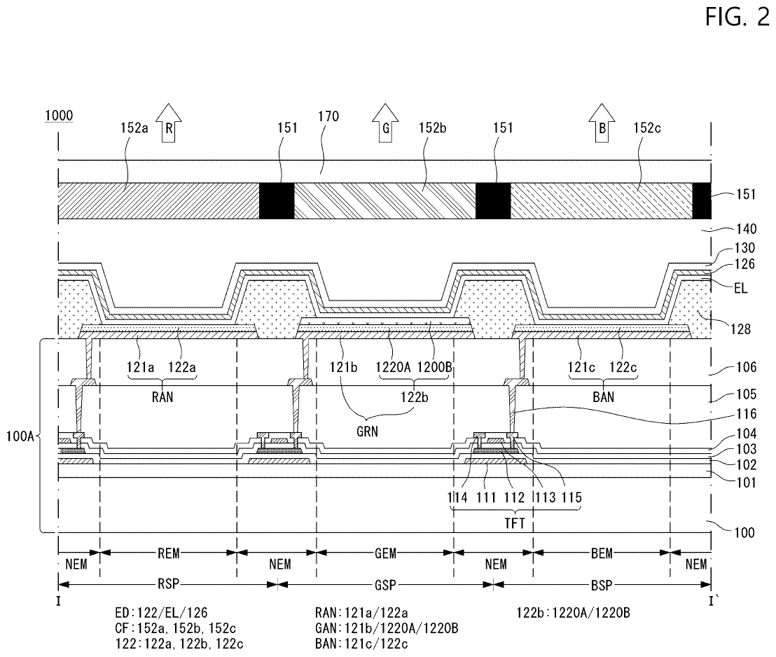

FIG. 1 is a sectional view schematically showing a light emitting display device according to a first embodiment of the present disclosure, and FIG. 2 is a sectional view showing a light emitting display device according to an embodiment of the present disclosure.

As shown in FIG. 1, the light emitting display device 1000A according to the first embodiment of the present disclosure includes an array substrate 100A on which a red subpixel RSP, a green subpixel GSP, and a blue subpixel BSP are disposed and a light emitting device ED1 including a red anode PAN, a green anode GAN, and a blue anode BAN disposed on the red subpixel RSP, the green subpixel GSP, and the blue subpixel BSP, respectively, each of the red anode RAN, the green anode GAN, and the blue anode BAN including a reflective electrode and a transparent anode, an intermediate layer EL disposed on the red, green, and blue anodes PAN, GAN, and BAN, and a semi-transmissive cathode 126 disposed on the intermediate layer EL.

Here, each of the red anode PAN, the green anode GAN, and the blue anode BAN includes a first reflective electrode 121a, a second reflective electrode 121b, and a third reflective electrode 121c. And each of the red anode RAN, the green anode GAN, and the blue anode BAN includes a first transparent anode 122a, a second transparent anode 122b, and a third transparent anode 122c respectively on the first reflective electrode 121a, the second reflective electrode 121b, and the third reflective electrode 121c. Each of the first transparent anode 122a, the second transparent anode 122b, and the third transparent anode 122c is in contact with the first reflective electrode 121a, the second reflective electrode 121b, and the third reflective electrode 121c In the red anode RAN, the green anode GAN, and the blue anode BAN, each of the first to third reflective electrodes 121a, 121b, and 121c is made of a reflective electrode material, such as a highly efficient reflective electrode material capable of inducing total reflection on an upper surface thereof. For example, each of the first to third reflective electrodes 121a, 121b, and 121c can be formed as a multilayer structure, such as a stack structure of aluminum (Al) and titanium (Ti) (Ti/Al/Ti), a stack structure of aluminum (Al) and ITO (ITO/Al/ITO), an APC (Ag/Pd/Cu) alloy, and a stack structure of an APC alloy and ITO (ITO/APC/ITO), or a stack structure of silver (Ag) and a molybdenum/titanium alloy (Ag/MoTi), or can include a monolayer structure made of any one selected from among silver (Ag), aluminum (Al), molybdenum (Mo), gold (Au), magnesium (Mg), calcium (Ca), and barium (Ba), or an alloy of two or more thereof.

The first to third reflective electrodes 121a, 121b, and 121c can be made of the same material and have the same thickness.

The first to third reflective electrodes 121a, 121b, and 121c can be provided together in the same process but separately patterned for each of the subpixels RSP, GSP, and BSP. When the first to third reflective electrodes 121a, 121b, and 121c are provided in the same process, the number of masks can be reduced.

At least one of first to third transparent anodes 122a, 122b, and 122c of each of the red anode PAN, the green anode GAN, and the blue anode BAN can have a thickness different from the thicknesses of the other transparent anodes. In the example shown in FIG. 1, the second transparent anode 122b includes a stack of a first transparent anode layer 1220A and a second transparent anode layer 1220B.

The first transparent anode 122a of the red subpixel RSP, the first transparent anode layer 1220A of the green subpixel GSP, and the third transparent anode 122c of the blue subpixel BSP can be patterned using the same material in the same process so as to have the same thickness. For example, the first transparent anode 122a of the red subpixel RSP, the first transparent anode layer 1220A of the green subpixel GSP, and the third transparent anode 122c of the blue subpixel BSP are made of the same transparent metal oxide, such as indium-tin oxide, indium-zinc oxide, or indium-tin-zinc oxide.

The green subpixel GSP can further selectively include a second transparent anode layer 1220B provided on the first transparent anode layer 1220A. The second transparent anode layer 1220B can be made of a transparent metal oxide different from the first transparent anode layer 1220A. For example, when the first transparent anode layer 1220A is made of indium-tin oxide, the second transparent anode layer 1220B can include indium-zinc oxide. Alternatively, when the first transparent anode layer 1220A is made of indium-zinc oxide, the second transparent anode layer 1220B can include indium-tin oxide.

Each of the first transparent anode 122a and the third transparent anode 122c has the first transparent anode layer 1220A of the second transparent anode 122b with the same thickness as the indium-tin oxide layer of the second transparent anode 122b. Each of the first transparent anode 122a and the third transparent anode 122c may not have the second transparent anode layer 1220B, unlike the second transparent anode 122b. In a light emitting display device according to another embodiment of the present disclosure, each of the first transparent anode 122a and the third transparent anode 122c can include an indium-zinc oxide layer having a thickness different from that of the second transparent anode layer 1220B of the second transparent anode 122b.

The light transmittance of each of the first to third transparent anodes 122a, 122b, and 122c can be 80% or more in a visible light wavelength range.

In each of the subpixels RSP, GSP, and BSP, the semi-transmissive cathode 126 opposite the red anode RAN, the green anode GAN, and the blue anode BAN can include at least one of silver (Ag), ytterbium (Yb), magnesium (Mg), and strontium (Sr). In the light emitting device ED1, the semi-transmissive cathode 126 is opposite the first to third reflective electrodes 121a, 121b, and 121c of each of the red/green/blue anodes RAN, GAN, and BAN and is configured such that light is repeatedly reflected and re-reflected at the surface thereof through reflective characteristics thereof. At the same time, the semi-transmissive cathode 126 also has transmissive characteristics, whereby light is ultimately emitted therethrough. The semi-transmissive cathode 126 contributes to the strong cavity characteristics of the light emitting device ED1 through resonant induction by repeated reflection and re-reflection together with the first to third reflective electrodes 121a, 121b, and 121c of each of the red/green/blue anodes PAN, GAN, and BAN.

The semi-transmissive cathode 126 is thin enough to allow light transmission and has a light transmittance lower than that of the first to third transparent anodes 122a, 122b, and 122c in a visible light wavelength range. The semi-transmissive cathode 126 can have a transmittance of 30% to 90%. The semi-transmissive cathode 126 can have a thickness of approximately 30 Å to 200 Å.

The semi-transmissive cathode 126 can be made of, for example, AgYb or AgMg.

In each of the subpixels RSP, GSP, and BSP, an intermediate layer EL having the same vertical distance is interposed between the semi-transmissive cathode 126 and the red anode PAN, the green anode GAN, and the blue anode BAN. The intermediate layer EL may be disposed between the upper surfaces of the first to third transparent anodes 122a, 122b, and 122c and the semi-transmissive cathode 126. The intermediate layer EL disposed on the red anode PAN, the green anode GAN, and the blue anode BAN can include, for example, light emitting stacks including a light emitting layers BEML, GEML, and REML and charge generation layers CGL1 and CGL2 disposed between the light emitting stacks. The light emitting layers BEML, GEML, and REML may overlap each other while being spaced apart from each other with the charge generation layers CGL1 and CGL2 interposed therebetween.

The first light emitting stack can include a hole injection layer HIL, a first hole transport layer HTL1, a blue light emitting layer BEML, and a first electron transport layer ETL1.

The second light emitting stack can include a second hole transport layer HTL2, a green light emitting layer GEML, and a second electron transport layer ETL2.

The third light emitting stack can include a third hole transport layer HTL3, a red light emitting layer REML, a third electron transport layer ETL3, and an electron injection layer EIL.

In the light emitting display device 1000 according to the embodiment of the present disclosure, the intermediate layer EL is common to the red subpixel RSP, the green subpixel GSP, and the blue subpixel BSP, and does not require a fine metal mask having an opening for each light emitting portion, thereby providing excellent processability and very high yield.

The light emitting display device 1000A according to FIG. 1 has a red resonance distance, a green resonance distance, and a blue resonance distance corresponding respectively to the subpixels RSP, GSP, and BSP. In the green anode GAN provided in at least the green subpixel GSP, a second transparent anode 122b stacked with the first and second transparent anode layers 1220A and 1220B having a different structure from the other subpixels is provided. In the green subpixel GSP, therefore, the second transparent anode layer 1220B added differentially compared to the red subpixel RSP and the blue subpixel BSP is included within the resonance distance, whereby the green resonance distance can be longer each of than the red resonance distance and the blue resonance distance. The red resonance distance and the blue resonance distance may be equal to each other.

In addition, each of the first to third transparent anodes 122a, 122b, and 122c is made of a transparent metal oxide, compared to an organic material included in the intermediate layer EL, a metallic material such as indium, zinc, or tin can be included, and the refractive index of each of the first to third transparent anodes can be higher than that of the intermediate layer EL. Accordingly, in the light emitting device according to the structure of FIG. 1, each resonance distance is weighted according to the refractive index of the transparent metal oxide according to the first to third transparent anodes 122a, 122b, and 122c. For example, when calculating the resonance distance of each light emitting color, the weight of the transparent anode can be 1.1 times that of the intermediate layer.

The resonance distance of the red subpixel can be proportional to the thickness of the first transparent anode 122a, the resonance distance of the green subpixel can be proportional to the thickness of the second transparent anode 122b, and the resonance distance of the blue subpixel can be proportional to the thickness of the third transparent anode 122c.

Also, in the green subpixel GSP, the second transparent anode 122b further includes a transparent anode layer 1220B compared to other subpixels RSP and BSP, thereby enabling it to further include a green resonance distance proportional to the thickness of the second transparent anode 122b.

The sum of 1.1 times the thickness of the first transparent anode 122a and the total thickness of the intermediate layer EL, which is the first vertical distance, can be the red resonance distance.

The sum of 1.1 times the thickness of the second transparent anode 122b (1220A+1220B) and the first vertical distance can be the green resonance distance.

The sum of 1.1 times the thickness of the third transparent anode 122c and the first vertical distance can be the blue resonance distance.

For example, the emission peak of red light is 620 nm to 630 nm, the emission peak of green light is 530 nm to 540 nm, and the emission peak of blue light is 450 nm to 460 nm.

The formula described below or the resonance distance for each emission color can be calculated by considering the wavelength of the emission peak.

Referring to FIG. 1, the wavelength of blue light is short, the wavelength of red light is long, and the number of red light emitting nodes and the number of blue light emitting nodes generated from the red subpixel RSP and the blue subpixel BSP in the intermediate layer having the first vertical distance can be different from each other. The example shown is an example in which there are two red light emitting nodes and three blue light emitting nodes, but this is only an example, and the embodiment of the present disclosure is not limited thereto.

The emission peak wavelength of green light is shorter than that of red light and longer than that of blue light. However, the green subpixel GSP can further have a second transparent anode layer 1220B compared to the blue subpixel BSP, allowing for a longer green resonance distance. In this case, the number of green light emitting nodes can be matched to the number of blue light emitting nodes generated from the blue subpixel BSP at the green resonance distance generated via the intermediate layer EL and the second transparent anode 122b. The number of red light emitting nodes generated at the red resonance distance may be respectively different from the number of green light emitting nodes generated at the green resonance distance and the number of blue light emitting nodes generated at the blue resonance distance.

Meanwhile, in the embodiment of the light emitting display device according to the present disclosure, the second transparent anode layer 1220B further provided for each subpixel is not necessarily limited to the green subpixel. The second transparent anode layer 1220B can be provided in the blue subpixel RSP and the red subpixel RSP in the state in which the thickness of the second transparent anode layer 1220B is changed. In this case, the number of green light emitting nodes generated at the green resonance distance can differ from the number of blue light emitting nodes generated at the blue resonance distance.

The presence or absence of the second transparent anode layer 1220B and the thickness thereof are considered in conjunction with the overall thickness of the intermediate layer EL and can be adjusted according to the vertical resonance distances of red, green, and blue.

Referring to FIG. 1, the red resonance distance and the blue resonance distance can be the same, and the green resonance distance can be 800 Å or more than 800 Å greater than the red resonance distance by selectively providing a second transparent anode layer 1220B in the green subpixel GSP.

For example, the red resonance distance can be 2800 Å to 3100 Å or 4500 Å to 4800 Å, the green resonance distance can be 3600 Å to 3900 Å or 5100 Å to 5400 Å, the blue resonance distance can be 2800 Å to 3100 Å or 4000 Å to 4300 Å.

The vertical distance from an upper surface of the first transparent anode 122a to a lower surface of the red light emitting layer REML can be 300 Å to 1000 Å, 1800 Å to 2800 Å, or 3500 Å to 4500 Å.

The vertical distance from an upper surface of the second transparent anode 122b to a lower surface of the green light emitting layer GEML can be 800 Å to 1700 Å or 2300 Å to 3000 Å.

The vertical distance from an upper surface of the third transparent anode 122c to a lower surface of the blue light emitting layer BEML can be 200 Å to 800 Å, 1200 Å to 1800 Å, 2300 Å to 3000 Å, or 3500 Å to 4000 Å.

At least one light emitting layer included in the second light emitting stack and the third light emitting stack can be disposed so as to be vertically shifted by a first interval from the maximum emission peak position of the first reflective electrode, the second reflective electrode, and the third reflective electrode.

In the light emitting display device according to the embodiment of the present disclosure, the vertical positions of the green light emitting layer GEML and the red light emitting layer REML of at least the second and third light emitting stacks can be adjusted, and the specific range thereof will be described below based on the following experiments.

Here, referring to FIG. 2, the red anode RAN, the green anode GAN, and the blue anode BAN can be disposed on a planarization layer 106 disposed on the substrate 100.

Meanwhile, a capping layer 130 configured to protect the light emitting device ED1 and to enhance light emission efficiency can be provided on the semi-transmissive cathode 126. The capping layer 130 can include an inorganic capping layer and an organic capping layer.

In addition, a protective layer 140 having a sealing or protection function to cover the entirety of the array substrate 100A including the light emitting device ED can be further provided on the capping layer 130.

A red filter 152a, a green filter 152b, and a blue filter 152c are provided on the protective layer 140 so as to correspond to the red subpixel RSP, the green subpixel GSP, and the blue subpixel BSP, respectively.

In the light emitting display device according to the embodiment of the present disclosure, red subpixels RSP, green subpixels GSP, and blue subpixels BSP are repeated disposed on the array substrate 100A without white subpixels. When light is incident from the outside in the state in which the subpixels overlap the color filters 152a, 152b, and 152c, the wavelength of the light is restricted through the color filters 152a, 152b, and 152c, whereby it is possible to achieve excellent external light reflection prevention effects without a polarizer.

The array substrate 100A includes a configuration including the substrate 100 shown in FIG. 2, a transistor TFT, and a planarization layer 106.

Specifically, the configuration of the light emitting display device 1000 will be described with reference to FIG. 2.

The substrate 100 can include at least one of a glass substrate, a plastic layer, and a metal plate having certain supporting force. The substrate 100 can be made of a flexible material. For example, if the substrate 100 has a plurality of layers, the substrate 100 can have a structure in which a first organic layer, an inorganic insulating layer, and a second organic layer are stacked. The outermost first organic layer can prevent or minimize the introduction of external impurities. The second organic layer can enable surface planarization of a formation surface of an inner array structure and prevent or minimize charge transfer or impurity transfer from the outside to the inside. The inorganic insulating layer provided between the first and second organic layers can prevent or minimize moisture permeation diffusion between the first and second organic layers and the transfer of conductive impurities to the second organic layer.

A first insulating layer 101 can be provided on the substrate 100. The first insulating layer 101 can function as a buffer layer or an active buffer layer. The buffer layer or the active buffer layer can prevent or minimize impurities from being transferred from the bottom to the top of the wiring and the active layer included in the internal array, and can support and protect the upper structure. The first insulating layer 101 can have multiple layers.

A thin-film transistor TFT and a storage capacitor can be disposed on the first insulating layer 101 for each of the subpixels RSP, GSP, and BSP.

A light blocking layer 111 configured to prevent or minimize light from being transmitted from the lower side to the active layer 112 of the thin-film transistor TFT can be provided on the first insulating layer 101.

A second insulating layer 102 for insulation can be disposed between the light blocking layer 111 and the active layer 112.

The thin-film transistor TFT can be disposed in each of the plurality of subpixels on the second insulating layer 102. For example, the thin-film transistor TFT can include an active layer 112, a gate electrode 113 overlapping the active layer 112 with a third insulating layer 103 interposed therebetween, and a first source drain electrode 114 and a second source drain electrode 115 connected to both sides of the active layer 112.

In an example, the storage capacitor can include a first storage electrode and a second storage electrode overlapping each other. At least one of the first and second storage electrodes can be made of the same material as the active layer 112, and the other can include the same material as at least one of the gate electrode 113, the first and second source drain electrodes 114 and 115, and the light blocking layer 111.

The third insulating layer 103 between the active layer 112 and the gate electrode 113 can function as a gate insulating layer.

The active layer 112 can include, for example, a silicon-based or oxide semiconductor. The silicon-based semiconductor can also include crystalline and/or amorphous silicon. The oxide semiconductor can include at least one of gallium oxide, tin oxide, zinc oxide, indium oxide, iron oxide, and indium-gallium-zinc oxide. In some cases, the oxide semiconductor layer can be formed as a plurality of layers having different materials or different material composition ratios. Each subpixel can include a plurality of thin-film transistors, and the thin-film transistors can be located on different layers. For example, each subpixel of the substrate 100 can include a plurality of thin-film transistors having different active layers. In an example, the first thin-film transistor can be disposed closer to the substrate 100 as a silicon-based active layer, and the second thin-film transistor can be located higher than the first thin-film transistor as an active layer made of an oxide semiconductor.

The active layer 112 can include a channel area overlapping with the gate electrode 113 and source/drain areas connected to the first and second source drain electrodes 114 and 115, respectively.

The third insulating layer 103 can be selectively disposed on the channel area of the active layer 112 so as to correspond thereto, and can be provided on the entire surface of the substrate 100 except for the area through which the first and second source drain electrodes 114 and 115 extend. The third insulating layer 103 can perform a function of insulating the active layer 112 and the gate electrode 113 from each other. The third insulating layer 103 can be made of an inorganic insulating material, such as a silicon oxide (SiOx) layer, a silicon nitride (SiNx) layer, a silicon oxynitride (SiOxNy) layer, or a multilayer layer thereof.

The gate electrode 113 can be formed on the third insulating layer 103. The gate electrode 113 can be disposed so as to face the active layer 112 with the third insulating layer 103 interposed therebetween.

A fourth insulating layer 104 configured to cover and protect the gate electrode 113 can be formed on the gate electrode 113. In addition, the fourth insulating layer 104 can perform a function of protecting at least one electrode of the thin-layer transistor TFT, such as the gate electrode 113 and the active layer 112. The fourth insulating layer 104 can be made of an inorganic insulating material. For example, the fourth insulating layer 104 can be made of a silicon oxide (SiOx) layer, a silicon nitride (SiNx) layer, a silicon oxynitride (SiOxNy) layer, or a multilayer layer thereof.

The first source drain electrode 114 and the second source drain electrode 115 can be disposed on the fourth insulating layer 104. The fourth insulating layer 104 and the third insulating layer 103 can have contact holes provided therein such that the first and second source drain electrodes 114 and 115 contact both ends of the active layer 112, whereby the corresponding areas can be removed.

The gate electrode 113 and the first and second source drain electrodes 114 and 115 can each be formed as a single layer or multiple layers.

When each of the gate electrode 113 and the first and second source drain electrodes 114 and 115 is formed as a single layer, each of the gate electrode 113 and the first and second source drain electrodes 114 and 115 can be made of any one selected from the group consisting of molybdenum (Mo), aluminum (Al), chromium (Cr), gold (Au), titanium (Ti), nickel (Ni), neodymium (Nd), and copper (Cu) or an alloy thereof. In addition, when each of the gate electrode 113 and the first and second source drain electrodes 114 and 115 is formed as multiple layers, each of the gate electrode 113 and the first and second source drain electrodes 114 and 115 can be formed as a dual layer of molybdenum/aluminum-neodymium, molybdenum/aluminum, titanium/aluminum, or copper/molytitanium. Alternatively, each of the gate electrode 113 and the first and second source drain electrodes 114 and 115 can be formed as a triple layer of molybdenum/aluminum-neodymium/molybdenum, molybdenum/aluminum/molybdenum, titanium/aluminum/titanium, or molytitanium/copper/molytitanium.

However, the present disclosure is not limited thereto, and each of the gate electrode 113 and the first and second source drain electrodes 114 and 115 can be formed as multiple layers made of any one selected from the group consisting of molybdenum (Mo), aluminum (Al), chromium (Cr), gold (Au), titanium (Ti), nickel (Ni), neodymium (Nd), and copper (Cu) or an alloy thereof.

The first to fourth insulating layers 101, 102, 103, and 104 can each be made of an inorganic insulating layer. The inorganic insulating layer can be, for example, at least one of a silicon oxide layer, a silicon nitride layer, and a silicon oxynitride layer.

A first planarization layer 105 and a second planarization layer 106 can be provided on the first to fourth insulating layers 101, 102, 103, and 104. The first planarization layer 105 can include a contact hole in which a connection electrode 116 connected to the second source drain electrode 115 is provided. The second planarization layer 106 is disposed so as to cover the connection electrode 116 and the first planarization layer 105. The first and second planarization layers 105 and 106 can each include an organic material. The organic material can include at least one of an acrylic resin, a phenolic resin, a polyimide resin, an unsaturated polyester resin, a polyamide resin, benzocyclobutene, a polyphenylene resin, and a polyphenylene sulfide resin.

In an example, the connection electrode 116 can be made of any one selected from the group consisting of molybdenum (Mo), aluminum (Al), chromium (Cr), gold (Au), titanium (Ti), nickel (Ni), neodymium (Nd), and copper (Cu) or an alloy thereof. However, the embodiment of the present disclosure is not limited thereto. In some cases, the connection electrode 116 can be omitted. When the connection electrode 116 is omitted, one of the first and second source drain electrodes 114 and 115 can be directly connected to the red anode RAN, the green anode GAN, and the blue anode BAN of the light emitting device ED.

The light emitting device ED includes a stack of anodes RAN, GAN, and BAN, an intermediate layer EL, and a cathode 126.

Each of the red, green, and blue anodes RAN, GAN, and BAN can include a reflective electrode and a transparent anode, thereby performing an anode function. The red, green, and blue anodes RAN, GAN, and BAN can be connected to the transistor TFT via the second planarization layer 106 and the first planarization layer 105. In the example shown, the connection electrode 116 is further provided between the anodes RAN, GAN, and BAN and the transistor TFT, the transistor TFT and the connection electrode 116 are connected to each other, and the connection electrode 116 and the anodes RAN, GAN, and BAN are connected to each other. However, the connection electrode 116 may not be provided, and the second source drain electrode 115 of the transistor TFT can be directly connected to the anodes RAN, GAN, and BAN of the light emitting device ED. The bank 128 may cover the edge portions of the anodes RAN, GAN and BAN.

Each of the anodes RAN, GAN, and BAN can include reflective electrodes 121a, 121b, and 122c made of a metal with high reflectivity. For example, each of the anodes RAN, GAN, and BAN can be formed as a multilayer structure, such as a stack structure of aluminum (Al) and titanium (Ti) (Ti/Al/Ti), an APC (Ag/Pd/Cu) alloy, or a stack structure of silver (Ag) and a molybdenum/titanium alloy (Ag/MoTi), or a single layer structure made of any one selected from among silver (Ag), aluminum (Al), molybdenum (Mo), gold (Au), magnesium (Mg), calcium (Ca), and barium (Ba) or an alloy of two or more thereof.

An intermediate layer EL is provided on the red, green, and blue anodes RAN, GAN, and BAN. The disposition of the intermediate layer EL will be described below.

The light emitting device ED of each of the subpixels RSP, GSP, and BSP is provided with the red, green, and blue anodes RAN, GAN, and BAN and the semi-transmissive cathode 126, with the intermediate layer EL including three or more light emitting stacks and two or more charge generation layers therebetween. In addition to the light emitting layers BEML, GEML, and REML in each light emitting stack, functional layers, such as a hole injection layer HIL, a hole transport layer HTL, an electron blocking layer, a hole blocking layer, an electron transport layer ETL, and an electron injection layer EIL, can be further included. The intermediate layer EL of the light emitting display device according to the embodiment of the present disclosure has a tandem structure, the red light emitting layer REML, the green light emitting layer GEML, and the blue light emitting layer BEML in the tandem structure exhibit strong cavity characteristics in each light emitting device ED, and at least one light emitting layer is disposed in a state of being vertically shifted from the upper surface of the reflective electrode by a certain interval in order to mitigate viewing angle sensitivity. When the intermediate layer EL includes three light emitting stacks, the shifted interval of the light emitting layer farther from the reflective electrodes 121a, 121b, and 121c can be greater than that of the light emitting layer closer to the reflective electrodes 121a, 121b, and 121c. The blue light emitting layer BEML may be disposed in the intermediate layer EL so as to correspond to blue light emitting nodes at the blue resonance distance, the green light emitting layer GEML may be vertically shifted by a first interval from green light emitting nodes at the green resonance distance, and the red light emitting layer REML may be vertically shifted by a second interval from red light emitting nodes at the red resonance distance.

The intermediate layer EL can have the same structure in the subpixels RSP, GSP, and BSP.

When voltage is applied to the anodes PAN, GAN, and BAN and the semi-transmissive cathode 126, a vertical electric field is generated therebetween, causing holes and electrons to move toward the organic light emitting layer through the hole injection layer and the hole transport layer and the electron injection layer and the electron transport layer, respectively. In the organic light emitting layer, the holes and the electrons combine to form excitons, and when the excitons transit from an excited state to a ground state, light is emitted.

The semi-transmissive cathode 126 can be a common layer that is commonly disposed in the subpixels SP and applies the same voltage. To this end, the semi-transmissive cathode 126 can extend from an active area to a part of a non-active area outside of the active area. The active area of the array substrate 100A includes a plurality of subpixels and displays an image.

The semi-transmissive cathode 126 can include a semi-transmissive conductive material, such as silver (Ag), ytterbium (Yb), magnesium (Mg), strontium (Sr), or an alloy of magnesium (Mg) and ytterbium (Yb), or an alloy of magnesium (Mg) and silver (Ag). When the semi-transmissive cathode 126 includes a semi-transmissive conductive material, light emission efficiency can be increased by the microcavity effect. When the cathode 126 includes a semi-transmissive conductive material, the thickness of the cathode 126 can be sufficiently thin to allow light to pass therethrough.

Each of the red, green, and blue anodes PAN, GAN, and BAN can include a reflective electrode to prevent or minimize light generated in the intermediate layer EL from being transmitted to the shielding components under the anodes PAN, GAN, and BAN. Light generated in the intermediate layer EL can resonate between the semi-transmissive cathode 126 and the anodes RAN, GAN, and BAN, and can ultimately be emitted upward through the semi-transmissive cathode 126. Since each of the anodes RAN, GAN, and BAN includes reflective electrodes 121a, 121b, and 121c, the light emitted from the light emitting device ED can be seen in the light emitting portions REM, GEM, and BEM without affecting the disposition thereof even if overlapping the wiring and the transistor TFT.

The light emitting display device according to the embodiment of the present disclosure is a top emission type light emitting display device that emits light upward. In this case, each of the anodes RAN, GAN, and BAN includes a reflective electrode, and light generated in the intermediate layer EL resonates between the anode RAN, GAN, and BAN and the cathode 126 through reflection and re-reflection and is finally emitted toward the cathode 126.

A capping layer 130 configured to enhance the light emission effect is provided on the semi-transmissive cathode 126. A protective layer 140 is provided on the capping layer 130.

The protective layer 140 can be a single layer or multiple layers. When the protective layer 140 is multiple layers, at least one inorganic encapsulation layer and at least one organic encapsulation layer can be stacked. The inorganic encapsulation layer can prevent or minimize moisture penetration, and the organic encapsulation layer can cover particles and planarize the surface. In a plane, the organic encapsulation layer can be located closer to the inner side than the inorganic encapsulation layer. In this case, the inorganic encapsulation layer can prevent or minimize moisture penetration from the side.

The protective layer 140 can include a transparent organic layer.

A shielding layer 151 and color filters CF (152a, 152b, and 152c) can be further directly provided on the protective layer 140. A cover member 170 may be disposed on the shielding layer 151 and the color filters CF.

In addition, a touch sensor can be provided in place of the protective layer 140. The touch sensor can include a touch buffer layer, a bridge layer, a touch insulating layer, a touch sensor layer, and a touch protective layer, wherein the shielding layer 151 and the color filters CF (152a, 152b, and 152c) can be disposed on the touch protective layer.

The light emitting display device is used for large-area displays, and the light emitting display device is required to display images without any sense of disparity from various viewing angles.

The light emitting display device according to the embodiment of the present disclosure can have high efficiency and high color reproduction in a large-area structure including a plurality of light emitting stacks and a charge generation layer.

In the light emitting display device according to the present disclosure, the structure of the transparent anode between the reflective electrode and the intermediate layer can be adjusted for each subpixel and the plurality of light emitting layers can be vertically spaced apart from each other to implement a strong cavity structure.

Each of the plurality of light emitting stacks can include a light emitting layer, and the vertical position of at least one light emitting layer can be adjusted in consideration of viewing angle sensitivity.

In the light emitting display device according to the present disclosure, it is possible to reduce viewing angle sensitivity by adjusting the vertical positions of the plurality of light emitting layers relative to the light emitting nodes, thereby preventing or minimizing poor visual perception when the viewing angle changes.

In the light emitting display device according to the present disclosure, each subpixel overlaps a color filter, whereby it is possible to prevent or minimize external light reflection without a separate polarizer.

In the light emitting display device according to the present disclosure, the light emitting layers of the subpixels commonly includes an intermediate layer, whereby it is possible to achieve high yield and high luminance efficiency and to prevent or minimize a sense of disparity when the viewing angle changes.

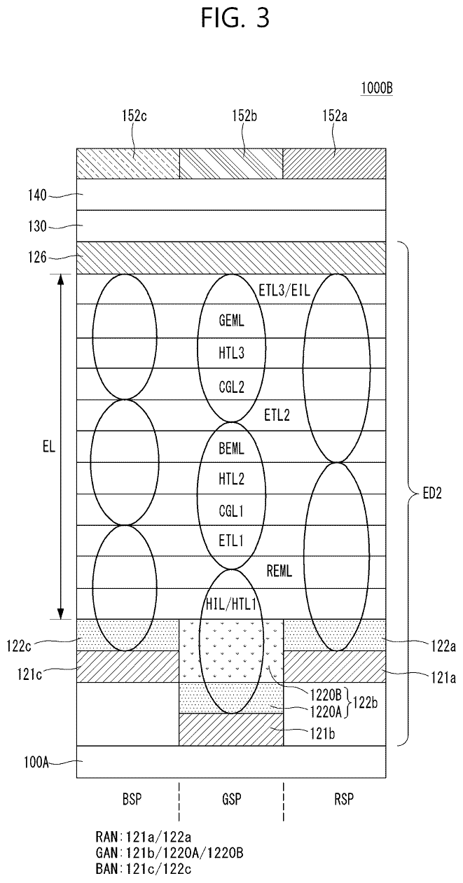

FIG. 3 is a sectional view schematically showing a light emitting display device according to a second embodiment of the present disclosure.

Compared to FIG. 1, an intermediate layer EL of a light emitting device ED2 of the light emitting display device 1000B according to the second embodiment of the present disclosure shown in FIG. 3 can include a first light emitting stack (HIL/HTL1/REML/ETL1) including a red light emitting layer REML, a first charge generation layer CGL1, a second light emitting stack (HTL2/BEML/ETL2) including a blue light emitting layer BEML, a second charge generation layer CGL2, and a third light emitting stack (HTL3/GEML/ETL3/EIL) including a green light emitting layer GEML, which are sequentially disposed.

The light emitting display device 1000B according to the second embodiment of the present disclosure shown in FIG. 3 is identical in configuration to the light emitting display device 1000A according to the first embodiment shown in FIG. 1 except for the disposition order of the intermediate layer EL, and therefore a description of the same configuration will be omitted or may be briefly provided.

Here, the position of the light emitting layer having the maximum emission peak from the upper surfaces of the reflective electrodes 121a, 121b, and 121c can be adjusted in the second and third light emitting stacks. In this case, the red light emitting layer REML of the first light emitting stack can be disposed at the position having the maximum peak from the upper surfaces of the reflective electrodes 121a, 121b, and 121c. The positions of the blue light emitting layer BEML of the second light emitting stack and the green light emitting layer GEML of the third light emitting stack can be shifted vertically by 50 Å to 500 Å from the position having the maximum peak from the upper surfaces of the reflective electrodes 121a, 121b, and 121c. More preferably, the positions of the blue light emitting layer BEML of the second light emitting stack and the green light emitting layer GEML of the third light emitting stack can be vertical shifted by 50 Å to 300 Å from the position having the maximum peak from the upper surfaces of the reflective electrodes 121a, 121b, and 121c.

The maximum emission peak position can be located at a second vertical distance d from the upper surfaces of the first reflective electrode, the second reflective electrode, and the third reflective electrode, wherein the second vertical distance can be given by equation

$$d = \frac{( 2 m - 1 ) λ}{4 n}$$

(where m is 1, 2, or 3, λ is the emission wavelength of the emission layer of the second light emitting stack or the third light emitting stack, and n is the refractive index of the intermediate layer).

The red resonance distance, the blue resonance distance, and the green resonance distance can be in ascending order.

At least one light emitting layer included in the second light emitting stack and the third light emitting stack can be disposed so as to be vertically shifted by a first interval from the maximum emission peak position of the first reflective electrode, the second reflective electrode, and the third reflective electrode.

Here, the first interval can be 50 Å to 500 Å. Alternatively, more preferably, the first interval can be 50 Å to 300 Å.

In some cases, the first interval actually applied depending on the process dispersion can be adjusted by about ±10 Å from the presented numerical range.

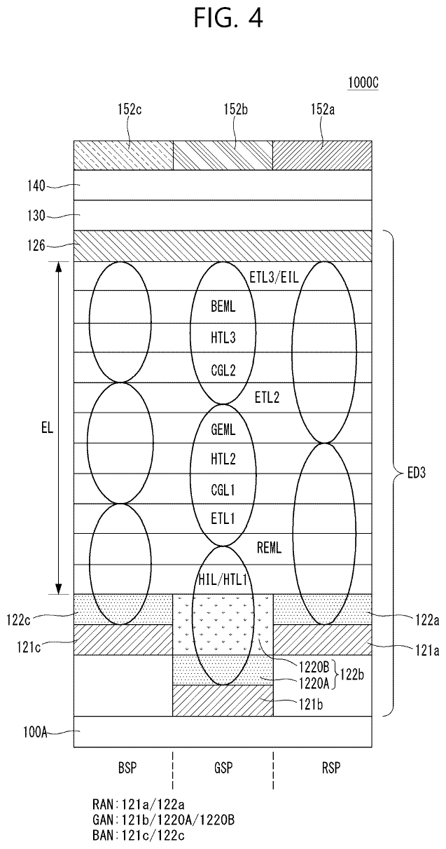

FIG. 4 is a sectional view schematically showing a light emitting display device according to a third embodiment of the present disclosure.

Compared to FIG. 1, an intermediate layer EL of a light emitting device ED3 of the light emitting display device 1000C according to the third embodiment of the present disclosure shown in FIG. 4 can include a first light emitting stack (HIL/HTL1/REML/ETL1) including a red light emitting layer REML, a first charge generation layer CGL1, a second light emitting stack (HTL2/GEML/ETL2) including a green light emitting layer GEML, a second charge generation layer CGL2, and a third light emitting stack (HTL3/BEML/ETL3/EIL) including a blue light emitting layer BEML, which are sequentially disposed.

The light emitting display device 1000C according to the third embodiment of the present disclosure shown in FIG. 4 is identical in configuration to the light emitting display device 1000A according to the first embodiment shown in FIG. 1 except for the disposition order of the intermediate layer EL, and therefore a description of the same configuration will be omitted or may be briefly provided.

Here, the position of the light emitting layer having the maximum peak from the upper surfaces of the reflective electrodes 121a, 121b, and 121c can be adjusted in the second and third light emitting stacks. In this case, the red light emitting layer REML of the first light emitting stack can be disposed at the position having the maximum peak from the upper surfaces of the reflective electrodes 121a, 121b, and 121c. The positions of the green light emitting layer GEML of the second light emitting stack and the blue light emitting layer BEML of the third light emitting stack can be shifted vertically by 50 Å to 500 Å from the position having the maximum peak from the upper surfaces of the reflective electrodes 121a, 121b, and 121c. More preferably, the positions of the green light emitting layer GEML of the second light emitting stack and the blue light emitting layer BEML of the third light emitting stack can be vertical shifted by 50 Å to 300 Å from the position having the maximum peak from the upper surfaces of the reflective electrodes 121a, 121b, and 121c.

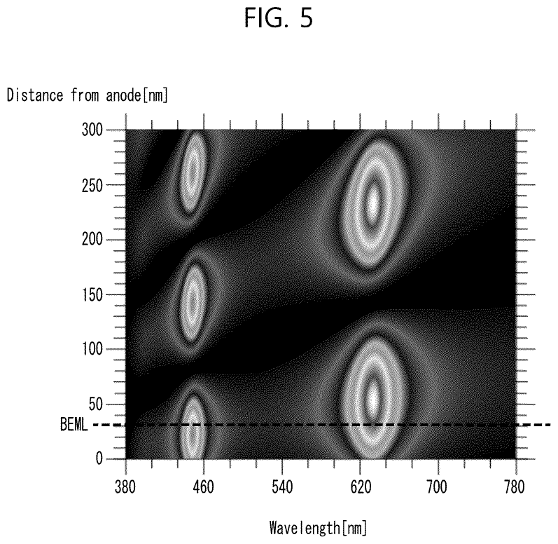

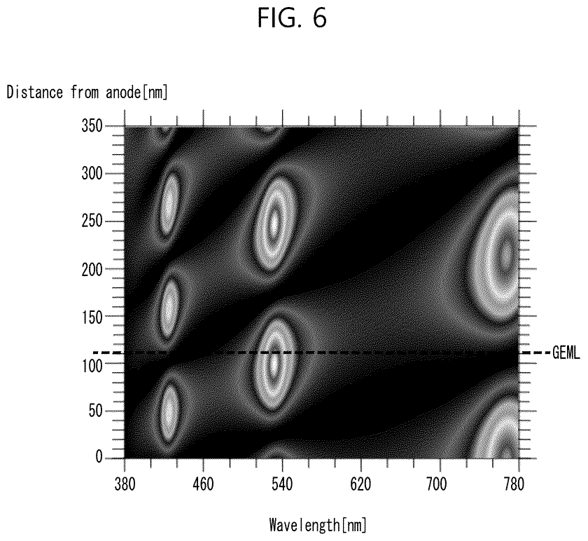

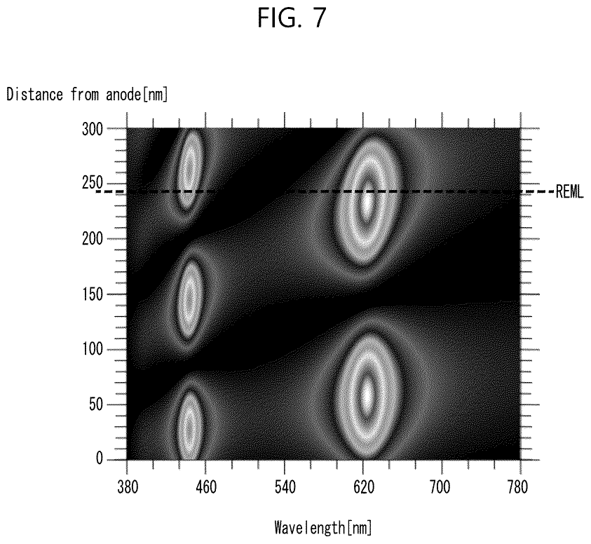

FIG. 5 is an example of a contour map showing a blue light emitting layer corresponding to the light emitting display device according to the embodiment of FIG. 1. FIG. 6 is an example of a contour map showing a green light emitting layer corresponding to the light emitting display device according to the embodiment of FIG. 1. FIG. 7 is an example of a contour map showing a red light emitting layer corresponding to the light emitting display device according to the embodiment of FIG. 1.

Referring to FIG. 5, the blue light emitting layer BEML can be located approximately at the first blue light emitting node from the reflective electrode. The vertical position of the blue light emitting layer BEML is located approximately higher than the blue light emitting node having the emission peak in order to reduce viewing angle sensitivity.

Referring to FIG. 6, the green light emitting layer GEML can be located approximately at the first green light emitting node from the reflective electrode. The vertical position of the green light emitting layer GEML is located approximately higher than the green light emitting node having the emission peak in order to reduce viewing angle sensitivity.

Referring to FIG. 7, the red light emitting layer REML can be located approximately at the second red light emitting node from the reflective electrode. The vertical position of the red light emitting layer REML is located approximately higher than the red light emitting node having the emission peak in order to reduce viewing angle sensitivity.

Table 1 below shows the color deviation (Δu′v′) characteristics when the distance from the upper surface of the reflective electrode to each of the green light emitting layer GEML and the red light emitting layer REML is changed.

TABLE 1

| Distance | | | | | | | | |
|---|---|---|---|---|---|---|---|---|
| from | | | | | | | | |
| reflective | | | | | | | | |
| electrode to | | | | | | | | |
| GEML/REML | | | | | | | | |
| [Å] | 2300 | 2350 | 2400 | 2450 | 2500 | 2550 | 2600 | 2650 |
| 950 | 0.026 | 0.025 | 0.024 | 0.025 | 0.028 | >0.028 | >0.028 | >0.028 |
| 1000 | 0.025 | 0.025 | 0.021 | 0.022 | 0.025 | >0.025 | >0.025 | >0.025 |
| 1050 | 0.024 | 0.021 | 0.018 | 0.017 | 0.02 | >0.028 | >0.02 | >0.02 |
| 1100 | 0.025 | 0.02 | 0.016 | 0.013 | 0.015 | 0.02 | >0.02 | >0.02 |
| 1150 | 0.028 | 0.023 | 0.017 | 0.011 | 0.011 | 0.015 | 0.02 | >0.02 |
| 1200 | >0.028 | >0.023 | 0.0227 | 0.015 | 0.018 | 0.012 | 0.116 | 0.022 |
| 1250 | >0.028 | >0.023 | >0.027 | 0.023 | 0.016 | 0.011 | 0.113 | 0.019 |

In the structure of FIG. 1, when the position of the green light emitting layer is vertically spaced apart from the upper surfaces of the transparent anodes 122a, 122b, and 122c by approximately 1000 Å and the position of the red light emitting layer REML is vertically spaced apart from the upper surfaces of the transparent anodes 122a, 122b, and 122c by 2350 Å, the green light emitting layer has the optimum green emission peak and the red light emitting layer has the optimum red emission peak.

In the embodiment of the present disclosure, the area where the color deviation (Δu′v′) characteristics is 0.020 or less is found through adjustment within a range of 50 Å to 500 Å considering that color deviation characteristics appear when each of the green light emitting layer GEML and the red light emitting layer REML located in the second and third light emitting stacks is located at the position having the optimum emission peak from the reflective electrode.

As such, when the light emitting layers GEML and REML of the second and third light emitting stacks are vertically shifted from the position having the optimum emission peak, the color deviation can be 0.020 or less even if the viewing angle is changed from the front to 60°, thereby preventing or minimizing the perception of viewing angle changes even if the viewing angle is changed from the front to 60°.

Hereinafter, the efficiency and color reproduction for each color were evaluated in a first experimental example EX1 having a structure including three light emitting stacks having the same anode structure, a second experimental example EX2 having a structure including four bottom emission type light emitting stacks R/B1/G/B2, a third experimental example EX3 having the structure shown in FIG. 1, a fourth experimental example EX4 having the structure shown in FIG. 3, and a fifth experimental example EX5 having the structure shown in FIG. 4.

In the third to fifth experimental examples EX3, EX4, and EX5, a second transparent anode layer having a thickness of 50 Å was added on a third transparent anode 122c in a blue subpixel, and the second transparent anode layer 1220B having a thickness of 770 Å was applied to a green subpixel.

In the third to fifth experimental examples EX3, EX4, and EX5, a semi-transmissive cathode was made of AgYb, and the thickness of the semi-transmissive cathode was 160 Å.

TABLE 2

| | EX1 | EX2 | EX3 | EX4 | EX5 |
|---|---|---|---|---|---|
| R efficiency | 6.4 | 16.2 | 48.3 | 55.4 | 44.8 |
| (Cd/A) | | | | | |
| G efficiency | 32.9 | 65.5 | 71.7 | 70.3 | 76.8 |
| (Cd/A) | | | | | |
| B efficiency | 5.8 | 8.2 | 4.6 | 4.7 | 4.6 |
| (Cd/A) | | | | | |
| Rx | 0.672 | 0.686 | 0.694 | 0.693 | 0.695 |
| Ry | 0.324 | 0.309 | 0.305 | 0.306 | 0.304 |
| Gx | 0.298 | 0.255 | 0.212 | 0.213 | 0.211 |
| Gy | 0.657 | 0.705 | 0.757 | 0.757 | 0.758 |
| Bx | 0.147 | 0.154 | 0.159 | 0.160 | 0.158 |
| By | 0.057 | 0.048 | 0.027 | 0.028 | 0.027 |
| Bindex (B/By) | 101.8 | 170.8 | 170.4 | 167.9 | 170.4 |
| Δu′v′ | 0.016 | 0.012 | 0.016 | 0.014 | 0.018 |
| DCI coverage | 93.8 | 98.6 | 98.6 | 98.4 | 98.8 |
| (%) | | | | | |
| BT2020 (%) | 68.6 | 80.6 | 87.2 | 86.7 | 87.8 |

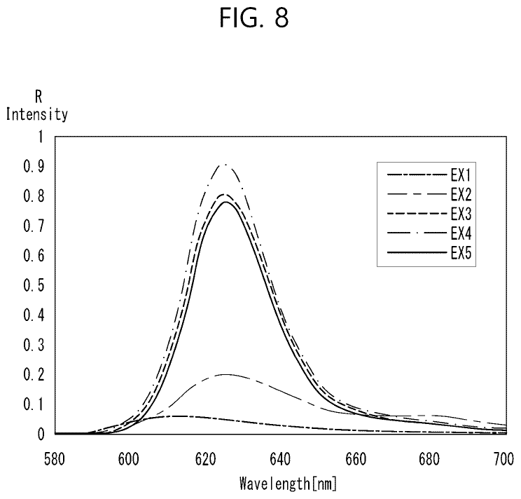

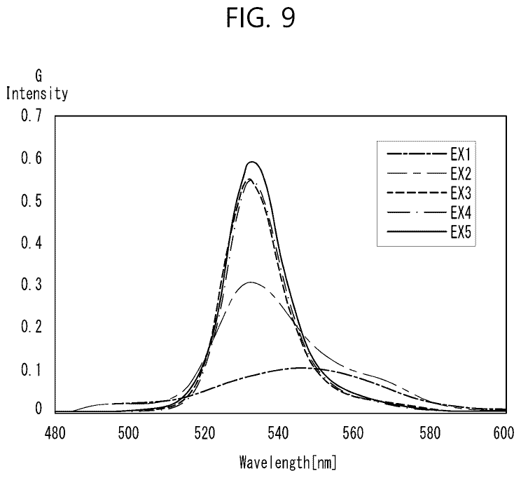

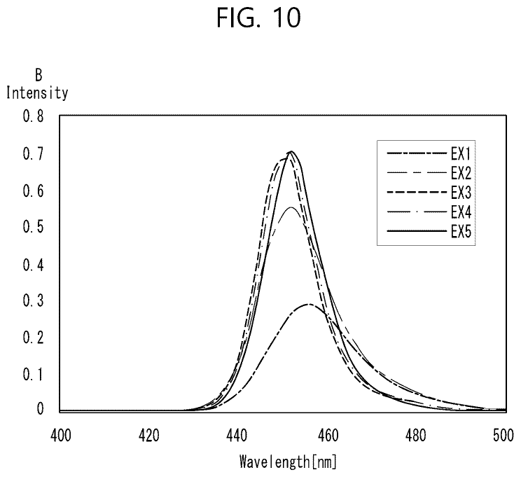

FIG. 8 is a graph showing red efficiencies of the first to fifth experimental examples. FIG. 9 is a graph showing green efficiencies of the first to fifth experimental examples. FIG. 10 is a graph showing blue efficiencies of the first to fifth experimental examples.

For reference, in the first experimental example EX1 having three light emitting stacks, an intermediate layer of a light emitting device has a stack structure of a first light emitting stack including a first blue emitting layer, a first charge generation layer, a second light emitting stack including a green emitting layer and a red emitting layer, a second charge generation layer, and a third light emitting stack including a second blue emitting layer.

In the second experimental example EX2 having four light emitting stacks, an intermediate layer of a light emitting device has a stack structure of a first light emitting stack including a red light emitting layer REML, a first charge generation layer, a second light emitting stack including a first blue light emitting layer, a second charge generation layer, a third light emitting stack including a green light emitting layer, a third charge generation layer, and a fourth light emitting stack including a second blue light emitting layer.

As shown in Table 2 and FIGS. 8 to 10, the third to fifth experimental examples EX3, EX4, and EX5 according to the first to third embodiments of the present disclosure have the same three-stack structure as the first experimental example EX1, but a semi-transmissive cathode and an anode structure having a differential structure are employed, whereby high efficiency and high color reproduction can be achieved.

In addition, compared to the first and second experimental examples EX1 and EX2 having an additional blue light emitting stack, the third to fifth experimental examples EX3, EX4, and EX5 according to the first to third embodiments of the present disclosure exhibit B index efficiency approximately equal to or higher than that of the second experimental example EX2 and higher than that of the first experimental example EX1.

Furthermore, while the first experimental example EX1, which has a bottom emission type structure and the same number of light emitting stacks, exhibits low efficiency and color reproduction due to weak cavity characteristics, it can be seen that the third to fifth experimental examples EX3, EX4, and EX5 solves the problems of low efficiency and color reproduction.

The third to fifth experimental examples EX3, EX4, and EX5 according to the first to third embodiments can have drive voltages similar to that of the first experimental example EX1 including the same number of light emitting stacks, and therefore it can be seen that the efficiency and color reproduction are significantly improved at the same power consumption.

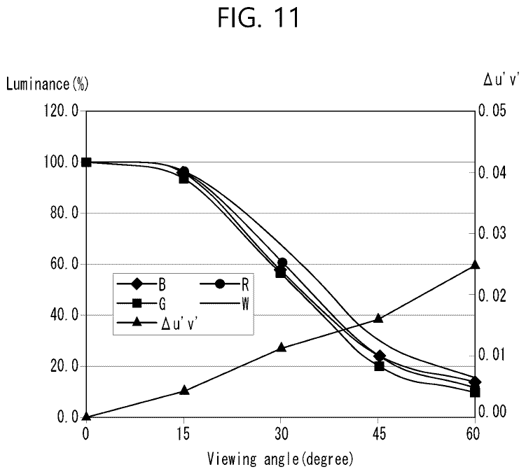

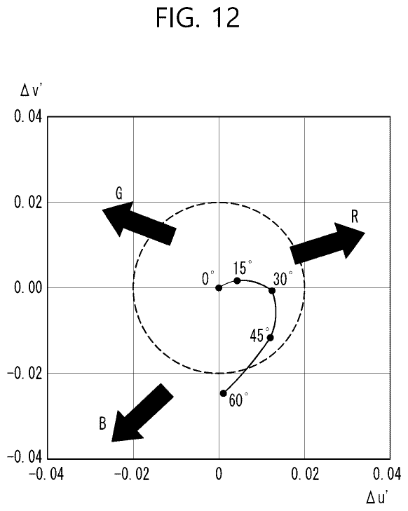

FIG. 11 is an example of a graph showing the luminous efficacies of the red, green, blue, and white and the color deviation characteristics according to the viewing angle variation when the light emitting layer is disposed at the maximum cavity position in the light emitting device according to the embodiment of FIG. 1. FIG. 12 is an example of a graph showing the color deviation characteristics of FIG. 11 for each viewing angle.

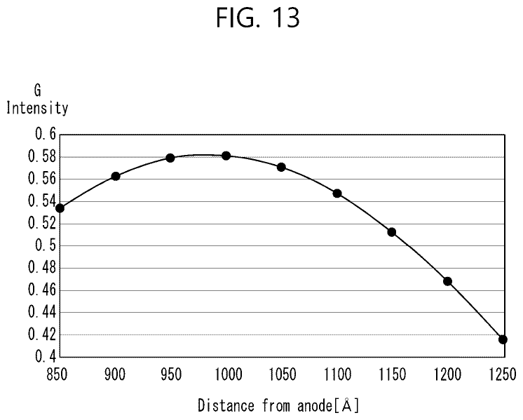

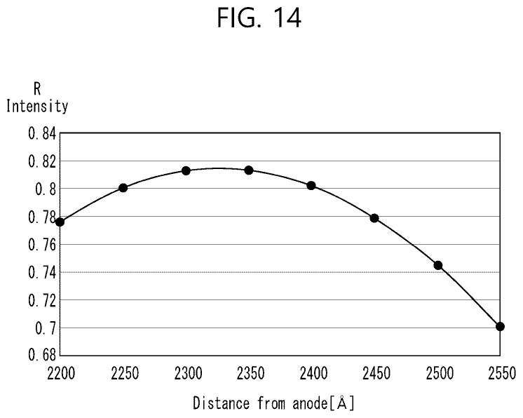

FIG. 13 is an example of a graph showing green intensity as a function of the distance from the upper surface of the transparent anode in the light emitting device according to the embodiment of FIG. 1. FIG. 14 is an example of a graph showing red intensity as a function of the distance from the upper surface of the transparent anode in the light emitting device according to the embodiment of FIG. 1.

In the light emitting device according to the embodiment shown in FIG. 1, when the light emitting layers are disposed at the maximum cavity position (the blue light emitting layer is vertically spaced apart from the transparent anode by 300 Å, the green light emitting layer is vertically spaced apart from the transparent anodes 122a, 122b, and 122c by approximately 1000 Å, and the red light emitting layer REML is vertically spaced apart from the transparent anodes 122a, 122b, and 122c by 2350 Å), the green light emitting layer has the optimum green emission peak and the red light emitting layer has the optimum red emission peak.

However, as shown in FIGS. 11 and 12, the degree to which the blue efficiency decreases with the viewing angle is less than that of the green and red efficiencies, whereby the blue efficiency increases at a high viewing angle change from 45° to 60° and thus blue color can become prominent. In addition, only when the color deviation exceeds 0.020, it is possible for viewers to perceive the viewing angle changes.

In the light emitting display device according to the embodiment of the present disclosure, the positions of the green light emitting layer and the red light emitting layer are shifted from the reflective electrode within a range where each of the green efficiency and the red efficiency is above a certain level, taking into account the color deviation changes in Table 1 and the green efficiency and red efficiency in FIGS. 13 and 14. The positions are shifted from the vertical position having approximately the maximum emission peak within a range of 50 Å to 500 Å. More preferably, the positions are shifted from the vertical position within a range of 50 Å o 300 Å.

Hereinafter, the viewing angle mitigation effect when the viewing angle is changed at each subpixel will be described.

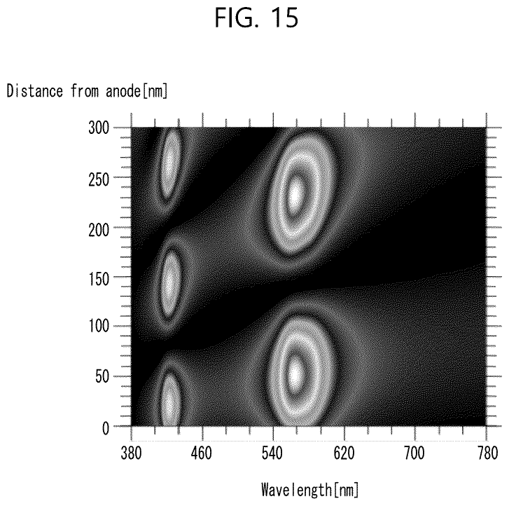

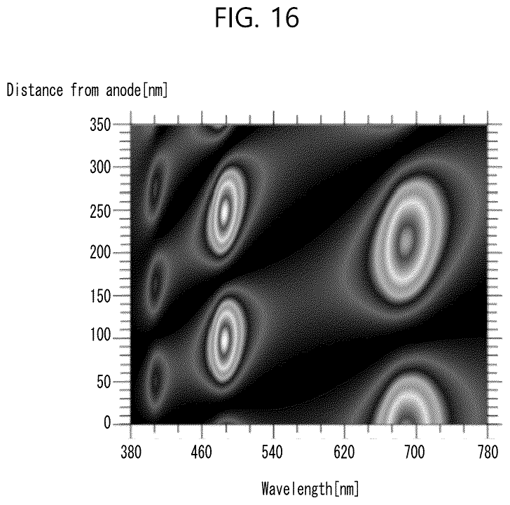

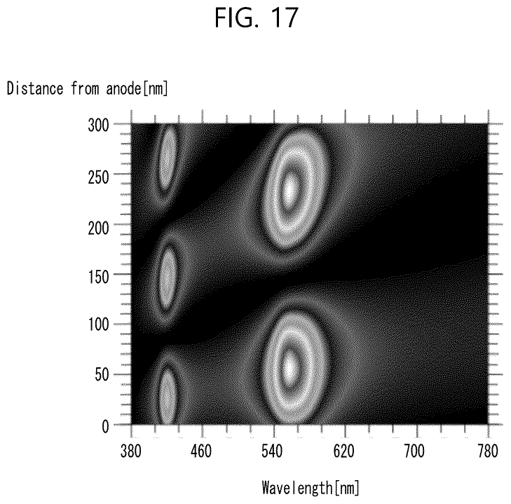

FIG. 15 is an example of a contour map of a blue subpixel at a viewing angle of 60° in the embodiment of FIG. 1. FIG. 16 is an example of a contour map of a green subpixel at a viewing angle of 60° in the embodiment of FIG. 1. FIG. 17 is an example of a contour map of a blue subpixel at a viewing angle of 60° in the embodiment of FIG. 1.

The front contour maps for red, green, and blue will be described with reference to FIGS. 5 to 7.

In the structure of FIG. 1, when the positions of the red light emitting layer and the green light emitting layer are shifted vertically from the position of the maximum emission peak, the change in light emission intensity moves outward from the center of each light emitting node of the contour map, as shown in FIGS. 5 to 7 and 15 to 17, whereby the level of recognition decreases when the viewing angle changes.

In the light emitting display device according to the present disclosure, the subpixels commonly include an intermediate layer including a plurality of light emitting layers, thereby achieving high yield.

In the light emitting display device according to the present disclosure, the light emitting devices commonly provided in the subpixels have a stack structure of a reflective electrode and a transparent anode in relation to the emission wavelength of each subpixel, and the thickness of the transparent anode is applied differently for each subpixel, whereby each subpixel can have a strong cavity corresponding to the emission wavelength. Therefore, the light emitting devices exhibit high efficiency and high color reproduction, thereby improving display efficiency.

As is apparent from the above description, in a light emitting display device according to the present disclosure, subpixels commonly include an intermediate layer including a plurality of light emitting layers, thereby achieving high yield.

In the light emitting display device according to the present disclosure, light emitting devices commonly provided in the subpixels have a stack structure of a reflective electrode and a transparent anode in relation to the emission wavelength of each subpixel, and the thickness of the transparent anode is applied differently for each subpixel, whereby each subpixel can have a strong cavity corresponding to the emission wavelength. Therefore, the light emitting devices exhibit high efficiency and high color reproduction, thereby improving display efficiency.

In the light emitting display device according to the present disclosure, red, green, and blue light emitting layers are vertically spaced apart from each other with a charge generation layer interposed therebetween, thereby enhancing the strong cavity effect.

In the light emitting display device according to the present invention, it is possible to mitigate viewing angle sensitivity by changing the position of the light emitting layer according to the vertical distance from the reflective electrode in the strong cavity structure, thereby preventing or minimizing the perception of viewing angle changes.

In the light emitting display device according to the present disclosure, each subpixel overlaps a color filter, whereby it is possible to effectively prevent or minimize external light reflection using the selective wavelength transmittance of the color filter without a separate polarizer.

A light emitting display device according to one embodiment of the present disclosure can comprise a substrate on which a red subpixel, a green subpixel, and a blue subpixel are disposed, a first reflective electrode, a second reflective electrode, and a third reflective electrode respectively at the red subpixel, the green subpixel, and the blue subpixel, a first transparent anode, a second transparent anode, and a third transparent anode respectively on the first reflective electrode, the second reflective electrode, and the third reflective electrode and in contact therewith, a semi-transmissive cathode opposite the first transparent anode, the second transparent anode, and the third transparent anode with an intermediate layer having the same vertical distance interposed therebetween and a red filter on the semi-transmissive cathode of the red subpixel, a green filter on the semi-transmissive cathode of the green subpixel, and a blue filter on the semi-transmissive cathode of the blue subpixel.

The intermediate layer can comprise a red light emitting layer, a green light emitting layer, and a blue light emitting layer overlapping each other while being spaced apart from each other with a charge generation layer interposed therebetween.

In a light emitting display device according to one embodiment of the present disclosure, the second transparent anode can have a thickness different from a thickness of each of the first transparent anode and the third transparent anode.

In a light emitting display device according to one embodiment of the present disclosure, the second transparent anode can comprise a stack of an indium-tin oxide layer and an indium-zinc oxide layer and the semi-transmissive cathode can comprise at least one of silver (Ag), ytterbium (Yb), magnesium (Mg), and strontium (Sr).

In a light emitting display device according to one embodiment of the present disclosure, each of the first transparent anode and the third transparent anode can comprise an indium-tin oxide layer having the same thickness as an indium-tin oxide layer of the second transparent anode, and does not comprise an indium-zinc oxide layer, or comprises an indium-zinc oxide layer having a thickness different from a thickness of an indium-zinc oxide layer of the second transparent anode.

In a light emitting display device according to one embodiment of the present disclosure, the intermediate layer can be disposed between upper surfaces of the first to third transparent anodes and the semi-transmissive cathode.

The intermediate layer can comprise a first light emitting stack comprising the blue light emitting layer, a first charge generation layer, a second light emitting stack comprising the green light emitting layer, a second charge generation layer, and a third light emitting stack comprising the red light emitting layer, which are sequentially disposed; or a first light emitting stack comprising the red light emitting layer, a first charge generation layer, a second light emitting stack comprising the blue light emitting layer, a second charge generation layer, and a third light emitting stack comprising the green light emitting layer, which are sequentially disposed; or a first light emitting stack comprising the red light emitting layer, a first charge generation layer, a second light emitting stack comprising the green light emitting layer, a second charge generation layer, and a third light emitting stack comprising the blue light emitting layer, which are sequentially disposed.

In a light emitting display device according to one embodiment of the present disclosure, a resonance distance of the red subpixel can be proportional to a thickness of the first transparent anode, a resonance distance of the green subpixel can be proportional to a thickness of the second transparent anode, and a resonance distance of the blue subpixel can be proportional to a thickness of the third transparent anode.

In a light emitting display device according to one embodiment of the present disclosure, a sum of 1.1 times a thickness of the first transparent anode to a first vertical distance can be a red resonance distance, a sum of 1.1 times a thickness of the second transparent anode and the first vertical distance can be a green resonance distance, and a sum of 1.1 times a thickness of the third transparent anode and the first vertical distance can be a blue resonance distance.

In a light emitting display device according to one embodiment of the present disclosure, the number of red light emitting nodes generated at the red resonance distance can be respectively different from the number of green light emitting nodes generated at the green resonance distance and the number of blue light emitting nodes generated at the blue resonance distance.

In a light emitting display device according to one embodiment of the present disclosure, the blue light emitting layer can be disposed in the intermediate layer so as to correspond to blue light emitting nodes at the blue resonance distance, the green light emitting layer can be vertically shifted by a first interval from green light emitting nodes at the green resonance distance, and the red light emitting layer can be vertically shifted by a second interval from red light emitting nodes at the red resonance distance.

In a light emitting display device according to one embodiment of the present disclosure, the red resonance distance and the blue resonance distance can be equal to each other, and the green resonance distance can be greater than the red resonance distance.

In a light emitting display device according to one embodiment of the present disclosure, the red resonance distance, the blue resonance distance, and the green resonance distance can be in ascending order.

In a light emitting display device according to one embodiment of the present disclosure, a red resonance distance can be 2800 Å to 3100 Å or 4500 Å to 4800 Å, a green resonance distance can be 3600 Å to 3900 Å or 5100 Å to 5400 Å, and a blue resonance distance can be 2800 Å to 3100 Å or 4000 Å to 4300 Å.

In a light emitting display device according to one embodiment of the present disclosure, a vertical distance from an upper surface of the first transparent anode to a lower surface of the red light emitting layer can be one of 300 Å to 1000 Å, 1800 Å to 2800 Å, and 3500 Å to 4500 Å. A vertical distance from an upper surface of the second transparent anode to a lower surface of the green light emitting layer can be 800 Å to 1700 Å or 2300 Å to 3000 Å. A vertical distance from an upper surface of the third transparent anode to a lower surface of the blue light emitting layer can be one of 200 Å to 800 Å, 1200 Å to 1800 Å, 2300 Å to 3000 Å, and 3500 Å to 4000 Å.

In a light emitting display device according to one embodiment of the present disclosure, at least one light emitting layer included in the second light emitting stack and the third light emitting stack can be vertically shifted by a first interval from maximum emission peak positions of the first reflective electrode, the second reflective electrode, and the third reflective electrode.

In a light emitting display device according to one embodiment of the present disclosure, the first interval can be 50 Å to 500 Å.

In a light emitting display device according to one embodiment of the present disclosure, the first interval can be 50 Å to 300 Å.

In a light emitting display device according to one embodiment of the present disclosure, the maximum emission peak position can be located at a second vertical distance (d) from upper surfaces of the first reflective electrode, the second reflective electrode, and the third reflective electrode.

The second vertical distance can be given by the following equation:

$$d = \frac{( 2 m - 1 ) λ}{4 n}$$

where m is 1, 2, or 3, λ is an emission wavelength of the emission layer of the second light emitting stack or the third light emitting stack, and n is a refractive index of the intermediate layer.

In a light emitting display device according to one embodiment of the present disclosure, each of the first transparent anode, the second transparent anode, and the third transparent anode can have a transmittance of 80% or more in a visible light wavelength range.

The semi-transmissive cathode can have transmittance lower than the transmittance of each of the first, second, and third transparent anodes and have a transmittance of 30% to 90% in the visible light wavelength range.

In a light emitting display device according to one embodiment of the present disclosure, the light emitting layer of the first light emitting stack can be disposed at the maximum emission peak position from the first reflective electrode, the second reflective electrode, and the third reflective electrode.

A light emitting display device according to one embodiment of the present disclosure can further comprise a capping layer and a protective layer between the semi-transmissive cathode and the red filter, the green filter, and the blue filter.

In the light emitting display device according to one or more embodiments of the present disclosure, the intermediate layer of the light emitting device is commonly provided in the subpixels. As a result, additional materials are not added, whereby environmental pollution can be prevented.

In addition, in the light emitting display device according to one or more embodiments of the present disclosure, it is possible to improve emission efficiency and power consumption efficiency by realizing clear color of each light emitting color by a strong cavity. Further, it is possible to improve the viewing angle sensitivity by adjusting the position of the light emitting layer from the reflective electrode.

In the light emitting display device according to one or more embodiments of the present disclosure, therefore, continuous applicability is possible, whereby ESG (environmental/social/governance) goals can be achieved.

What is claimed is:

1. A light emitting display device comprising:
a substrate on which a red subpixel, a green subpixel, and a blue subpixel are disposed;
a first reflective electrode, a second reflective electrode, and a third reflective electrode respectively at the red subpixel, the green subpixel, and the blue subpixel;
a first transparent anode, a second transparent anode, and a third transparent anode respectively on the first reflective electrode, the second reflective electrode, and the third reflective electrode;
a semi-transmissive cathode for each of the red, green and blue subpixels and opposite the first transparent anode, the second transparent anode, and the third transparent anode with an intermediate layer having a same vertical distance interposed therebetween; and
a red filter on the semi-transmissive cathode of the red subpixel, a green filter on the semi-transmissive cathode of the green subpixel, and a blue filter on the semi-transmissive cathode of the blue subpixel,
wherein the intermediate layer comprises a red light emitting layer, a green light emitting layer, and a blue light emitting layer overlapping each other while being spaced apart from each other with a charge generation layer interposed therebetween.

2. The light emitting display device according to claim 1, wherein the second transparent anode has a thickness different from a thickness of each of the first transparent anode and the third transparent anode.

3. The light emitting display device according to claim 1, wherein:
the second transparent anode comprises a stack of an indium-tin oxide layer and an indium-zinc oxide layer, and
the semi-transmissive cathode comprises at least one of silver (Ag), ytterbium (Yb), magnesium (Mg), and strontium (Sr).

4. The light emitting display device according to claim 1, wherein each of the first transparent anode and the third transparent anode comprises an indium-tin oxide layer having a same thickness as an indium-tin oxide layer of the second transparent anode, and does not comprise an indium-zinc oxide layer, or
comprises an indium-zinc oxide layer having a thickness different from a thickness of an indium-zinc oxide layer of the second transparent anode.

5. The light emitting display device according to claim 1, wherein:
the intermediate layer is disposed between upper surfaces of the first to third transparent anodes and the semi-transmissive cathode, and
the intermediate layer comprises:
a first light emitting stack comprising the blue light emitting layer, a first charge generation layer, a second light emitting stack comprising the green light emitting layer, a second charge generation layer, and a third light emitting stack comprising the red light emitting layer, which are sequentially disposed; or
a first light emitting stack comprising the red light emitting layer, a first charge generation layer, a second light emitting stack comprising the blue light emitting layer, a second charge generation layer, and a third light emitting stack comprising the green light emitting layer, which are sequentially disposed; or
a first light emitting stack comprising the red light emitting layer, a first charge generation layer, a second light emitting stack comprising the green light emitting layer, a second charge generation layer, and a third light emitting stack comprising the blue light emitting layer, which are sequentially disposed.

6. The light emitting display device according to claim 1, wherein:
a resonance distance of the red subpixel is proportional to a thickness of the first transparent anode,
a resonance distance of the green subpixel is proportional to a thickness of the second transparent anode, and
a resonance distance of the blue subpixel is proportional to a thickness of the third transparent anode.

7. The light emitting display device according to claim 1, wherein:
a sum of 1.1 times a thickness of the first transparent anode to a first vertical distance is a red resonance distance,
a sum of 1.1 times a thickness of the second transparent anode and the first vertical distance is a green resonance distance, and
a sum of 1.1 times a thickness of the third transparent anode and the first vertical distance is a blue resonance distance.

8. The light emitting display device according to claim 7, wherein a number of red light emitting nodes generated at the red resonance distance is different from a number of green light emitting nodes generated at the green resonance distance and a number of blue light emitting nodes generated at the blue resonance distance.

9. The light emitting display device according to claim 7, wherein:
the blue light emitting layer is disposed in the intermediate layer so as to correspond to blue light emitting nodes at the blue resonance distance,
the green light emitting layer is vertically shifted by a first interval from green light emitting nodes at the green resonance distance, and
the red light emitting layer is vertically shifted by a second interval from red light emitting nodes at the red resonance distance.

10. The light emitting display device according to claim 7, wherein:
the red resonance distance and the blue resonance distance are equal to each other, and
the green resonance distance is greater than the red resonance distance.

11. The light emitting display device according to claim 7, wherein the red resonance distance, the blue resonance distance, and the green resonance distance vary in ascending order.

12. The light emitting display device according to claim 1, wherein:
a red resonance distance ranges from 2800 angstrom (Å) to 3100 Å, or from 4500 Å to 4800 Å,
a green resonance distance ranges from 3600 Å to 3900 Å, or from 5100 Å to 5400 Å, and
a blue resonance distance ranges from 2800 Å to 3100 Å, or from 4000 Å to 4300 Å.

13. The light emitting display device according to claim 1, wherein:
a vertical distance from an upper surface of the first transparent anode to a lower surface of the red light emitting layer ranges from 300 angstrom (Å) to 1000 Å, or from 1800 Å to 2800 Å, or from 3500 Å to 4500 Å,
a vertical distance from an upper surface of the second transparent anode to a lower surface of the green light emitting layer ranges from 800 Å to 1700 Å, or from 2300 Å to 3000 Å, and
a vertical distance from an upper surface of the third transparent anode to a lower surface of the blue light emitting layer ranges from of 200 Å to 800 Å, or from 1200 Å to 1800 Å, or from 2300 Å to 3000 Å, or from 3500 Å to 4000 Å.

14. The light emitting display device according to claim 5, wherein at least one light emitting layer included in the second light emitting stack and the third light emitting stack is vertically shifted by a first interval from maximum emission peak positions of the first reflective electrode, the second reflective electrode, and the third reflective electrode.

15. The light emitting display device according to claim 14, wherein the first interval is 50 Å to 500 Å.

16. The light emitting display device according to claim 14, wherein the first interval is 50 Å to 300 Å.

17. The light emitting display device according to claim 14, wherein:
the maximum emission peak position is located at a second vertical distance (d) from upper surfaces of the first reflective electrode, the second reflective electrode, and the third reflective electrode, and
the second vertical distance is represented by equation:
$$d = \frac{( 2 m - 1 ) λ}{4 n}$$
where m is 1, 2, or 3, λ is an emission wavelength of an emission layer of the second light emitting stack or the third light emitting stack, and n is a refractive index of the intermediate layer.

18. The light emitting display device according to claim 1, wherein:
each of the first transparent anode, the second transparent anode, and the third transparent anode has a transmittance of 80% or more in a visible light wavelength range, and
the semi-transmissive cathode has a transmittance lower than the transmittance of one of the first, second, and third transparent anodes, and has a transmittance of 30% to 90% in the visible light wavelength range.

19. The light emitting display device according to claim 14, wherein the light emitting layer of the first light emitting stack is disposed at the maximum emission peak position from the first reflective electrode, the second reflective electrode, and the third reflective electrode.

20. The light emitting display device according to claim 1, further comprising a capping layer and a protective layer between the semi-transmissive cathode and the red filter, the green filter, and the blue filter.
